(19) United States
(12) Patent Application Publication
(10) Pub. No.: US 2003/0025202 A1
(43) Pub. Date: Feb. 6, 2003

(54) Semiconductor device having an external electrode

(75) Inventors: Kaoru Mikagi, Tokyo (JP); Akira Furuya, Tokyo (JP); Keisuke Hatano, Tokyo (JP)

Correspondence Address: PATENT GROUP, CHOATE, HALL & STEWART, EXCHANGE PLACE, 53 STATE STREET, BOSTON, MA, 02109, US

(73) Assignee: NEC Corporation

(21) Appl. No.: 10/197,149

(22) Filed: Jul. 17, 2002

(30) Foreign Application Priority Data
Jul. 17, 2001 (JP) 2001-216246

(51) Int. Cl. H01L 23/48

(52) U.S. Cl. 257/737

(57) ABSTRACT

An external electrode in a semiconductor device includes, from the bottom of a wafer, a wiring pad, first and second barrier metal layers, a solder-wetting film and a solder ball. The first barrier metal layer has a tensile internal stress and a granular crystalline structure, whereas the second barrier metal layer has a compressive internal stress and a pillar crystalline structure. The two-layer structure of the barrier metal film has an excellent barrier function against Sn diffusion from the solder ball and reduces the internal stress of the barrier metal film.

### BACKGROUND OF THE INVENTION

(a) Field of the Invention

The present invention relates to a semiconductor device having an external electrode and, more particularly, to a semiconductor device having an external electrode including a barrier metal electrode.

(b) Description of the Related Art

In a semiconductor device, an external electrode is generally formed by mounting a solder ball on a wiring pad connected to the internal wiring in the semiconductor device, The solder ball is bonded onto a corresponding electrode of a wiring board such as a printed circuit board. The semiconductor device is connected to an external circuit via the wiring board by the external electrode including such a solder ball, and also mechanically fixed onto the wiring board.

The semiconductor device generally includes a barrier metal electrode (electrode layer) interposed between the solder ball and the underlying wiring pad for preventing the tin (Sn) component in the solder ball from being diffused into the metallic film of the wiring pad. In general, Sn is the main component of the solder ball. Since the barrier metal electrode is subjected to an external stress applied through the solder ball, it is desired that the barrier metal electrode have a sufficient mechanical strength as well as the sufficient barrier function against the Sn diffusion.

FIG. 1 shows the structure of a conventional external electrode including the solder ball in a sectional view thereof. On a silicon substrate 10, a plurality of interlayer dielectric films and a plurality of interconnect layers are alternately disposed (not shown), wherein the topmost dielectric film 11 deposited by a PECVD (plasma-enhanced CVD) technique mounts thereon a wiring pad 12 made of Al. An underlying film 13 made of TiN/Ti is interposed between the wiring pad 13 and the interlayer dielectric film 11, thereby improving the adherence between the wiring pad 12 and the dielectric film 11 as well as the reliability of the interconnects. An insulating film 14 covering the wiring pad 12 has a two-layer structure including a plasma SiO₂ layer and a plasma SiON layer, the two-layer structure having therein a through-hole to expose the top of the wiring pad 12.

The top surface of the wiring pad 12 is coated with the TiN/Ti film 13 for improving the reliability of the interconnect, and the barrier metal electrode is formed on the TiN/Ti film 13. The barrier metal electrode includes an adherence Ti film 15, a nickel-vanadium (Ni—V) alloy film 16A acting as a barrier metal film, and a solder-wetting Cu film 17 which improves the wettability of the solder. These films are deposited on the entire surface by sputtering, and patterned to be left in the through-hole formed on the wiring pad 12 and the vicinity of the through-hole.

A polyimide coat 18 is formed on the entire surface and patterned to have an opening 19 for exposing the barrier metal electrode. A solder ball 20 is mounted on the barrier metal electrode and received in the opening 19. The barrier metal film 16A has a sufficient thickness and thus a sufficient barrier function for prevention of the Sn diffusion. The periphery of the barrier metal electrode is provided with an adherence TiW film 21 for improving the adherence between the barrier metal electrode and the polyimide coat 18.

FIG. 2 shows the structure of another conventional external electrode including a solder ball. The another external electrode is similar to the conventional external electrode of FIG. 1 except that the wiring pad is made of Al—Cu alloy in the another conventional external electrode. More specifically, the barrier metal electrode has a four-film structure including a Ti film 51 as a first conductive film, a sputtered Ni alloy film 52 as a second conductive film, a strike (strike-plating) Ni film 53 as a third conductive film, and a plating (ordinary-plating) Ni film 54 as a fourth conductive film.

The Ti film 51 and the sputtered Ni—V alloy film 52 are formed in a through-hole and the vicinity thereof on the interlayer dielectric film. A photoresist film 37 and a strike Ni film 53 are formed on the sputtered Ni—V alloy film 52 within the opening, and the plating Ni film 54 having a larger thickness is formed thereon. The solder ball 20 is formed by a plating technique on a solder-wetting Cu film formed on the plating Ni film 54. The plating technique for the strike Ni film 53 is such that the strike Ni film 53 having a thickness of 0.1 to 0.3 μm is formed by using a strike current, i.e., a momentarily larger plating current compared to the ordinary plating current, for assuring the adherence between the strike Ni film 53 and the sputtered Ni alloy film 52.

The external electrode structure of FIG. 1 is an example of forming a single barrier metal film 16A made of Ni alloy which prevents the Sn diffusion. It is to be noted that the barrier metal film 16A generally has a granular crystalline structure, wherein crystals are strangled in a complicated manner to have a curved crystalline boundary, thereby providing a higher barrier function for the Sn diffusion due to a larger path length of the Sn diffusion, which proceeds along the crystalline boundary.

FIG. 3 shows the relationship between the amount of wafer warp after sputtering of the barrier metal film and the crystal structure of the barrier metal film, which depends on the bias power during the sputtering of the barrier metal film. As understood from FIG. 3, the Ni alloy film having a granular crystal structure has a larger tensile strain therein. The larger tensile stress causes a problem in that the process for forming a barrier metal film having a large thickness generates a crack in the wiring pad 12 or peel-off of the insulator film 14 underlying the barrier metal film. To reduce the film stress, it may be considered that the Ni alloy film constituting the barrier metal film has a pillar crystalline structure instead of the granular crystalline structure. However, the pillar crystalline structure reduces the path length for the Sn diffusion due to the straight crystalline boundary, thereby degrading the barrier function for preventing the Sn diffusion, which is undesirable.

In the another conventional technique of FIG. 2, the plating Ni films 53 and 54 each having a large thickness is obtained by a three-layer structure including an electrode film 52 in addition to the plating Ni films 53 and 54, the electrode film 52 being used for plating thereon the Ni films 53 and 54. The electrode film 52 formed by sputtering is generally exposed to atmospheric air, which forms a passive Ni oxide film on the electrode film 52. The passive Ni oxide film is chemically stable, is difficult to remove, degrades the compactness of the plating Ni films 53 and 54 formed thereon, and reduces the bonding strength of the interface between the plating film 53 and the electrode film 52. In the conventional technique, a high-temperature eutectic solder material having a relatively smaller mechanical strength has been used for the solder ball 20, and thus the reduction of the bonding strength of the interface is not a critical problem in view of this mechanical strength of the solder ball 20 in the conventional technique.

In the meantime, a Pb-free solder material is increasingly used for the solder ball 20, the Pb-free solder material having an excellent ductility and a larger mechanical strength due to a higher Sn content therein. This allows the mechanical strength of the external electrode in the another conventional technique to be determined by the bonding strength of the interface between the plating Ni film 53 and the electrode Ni film 52 formed by sputtering. In addition, the development of smaller dimensions for the solder bumps reduces the bonding strength per solder bump, and highlights the problem of the bonding strength that is reduced due to the presence of the passive Ni oxide film formed on the electrode Ni film 52 in the another conventional technique.

### SUMMARY OF THE INVENTION

In view of the above, it is an object of the present invention to provide a semiconductor device having an external electrode including a barrier metal electrode or barrier metal film, which has an excellent barrier function against the Sn diffusion toward the wiring pad, and also has a reduced internal stress for preventing damages in the adjacent structure.

The present invention provides, in a first aspect thereof, a semiconductor device including an external electrode having a wiring pad, a barrier metal electrode and a solder ball consecutively formed on a wafer. The barrier metal electrode includes a plurality of barrier metal layers having common elements and having different internal stresses and/or different crystalline structures.

In accordance with the semiconductor device of the first aspect of the present invention, the external electrode as recited above allows the barrier metal electrode to have a relatively lower internal stress therein and to have a relatively larger film thickness, whereby the barrier metal electrode has an excellent barrier function without causing damages in the adjacent structure.

The term “barrier metal electrode” as used herein means an electrode structure including a single or plurality of conductive layers and interposed between the solder ball and the underlying wiring pad, wherein the conductive layer or layers include at least one barrier metal layer having a barrier function against the Sn diffusion from the solder ball. The barrier metal layer is preferably made of Ni or Ni alloy.

The present invention also provides, in a second aspect thereof, a semiconductor device including an external electrode having a wiring pad, a barrier metal electrode and a solder ball consecutively formed on a wafer. The barrier metal electrode includes at least five conductive layers including first through fifth conductive films consecutively formed on the wiring pad. The second and fourth conductive layers are barrier metal layers and the fourth conductive layer is a plating layer.

In accordance with the semiconductor device of the second aspect of the present invention, the third conductive layer formed on the second conductive layer formed as a barrier metal layer is used as a seed layer having a function for allowing the fourth conductive layer to be formed as an excellent plating layer having a higher adherence to the third conductive layer as compared with the second conductive layer having a barrier function.

The first conductive layer preferably acts as an adherence layer having an excellent adherence to the underlying layer, and the fifth conductive layer preferably acts as a wetting layer having an excellent wettability to the solder ball. The third and fifth conductive layers are preferably made of Cu. The barrier metal electrode preferably includes a sixth conductive layer as a protective layer, which protects edges of the patterned first through fifth conductive layers.

The present invention also provides, in a third aspect thereof, a method for manufacturing an external electrode in a semiconductor device, the method including the steps of: forming a wiring pad on a wafer; forming a plurality of barrier metal layers on the wiring pad; and forming a solder ball on the barrier metal layers.

The present invention also provides, in a fourth aspect thereof, a method for manufacturing an external electrode in a semiconductor device, the method including the steps of: forming a wiring pad on a wafer; forming a first barrier metal film made of nickel or nickel alloy on the wiring pad by sputtering in a vacuum ambient; forming a seed film on the first barrier metal film in the vacuum ambient; forming a second barrier metal film made of nickel by plating on the seed film; and forming a solder ball on the second barrier metal film.

The method of the third and fourth aspects of the present invention allows the semiconductor devices of the first and second aspects of the present invention to be formed.

The above and other objects, features and advantages of the present invention will be more apparent from the following description, referring to the accompanying drawings.

### BRIEF DESCRIPTION OF THE DRAWINGS

FIG. 1 is a sectional view of an external electrode in a conventional semiconductor device.

FIG. 2 is a sectional view of an external electrode in another conventional semiconductor device.

FIG. 3 is a graph showing the relationship between the wafer warp and the RF bias power, which determines the crystalline structure of the sputtered film.

FIG. 4 is a sectional view of an external electrode in a semiconductor device according to a first embodiment of the present invention.

FIGS. 5A and 5B are schematic sectional views of the Ni—V alloy films in the external electrode shown in FIG. 4.

FIG. 6 is a graph showing the relationship between the deposition rate of the Ni—V alloy film and the DC sputtering power.

FIG. 7 is a graph showing the relationship between the film stress in the sputtered Ni—V alloy film and the RF bias power and the relationship between the wafer warp and the RF bias powers with the DC sputtering power maintained constant.

FIG. 8 is a graph showing the relationship between the film stress in the sputtered Ni—V alloy film and the RF bias power and the relationship between the wafer warp and the RF bias power, with the sputtering power maintained constant.

FIG. 9 is a graph showing the relationship between the film stress in the sputtered Ni—V alloy film and the Ar flow rate, with the DC sputtering power maintained constant.

FIG. 10 is a graph showing the relationship between the film stress in the sputtered Ni—V alloy film and the DC sputtering power.

FIG. 11 is a graph showing the wafer warps at respective stages of fabrication of the external electrode, with the sputtering power, film thickness and the bias power being varied.

FIG. 12 is a table showing the relationship between the wafer warp and the process conditions in a three-layer structure of the barrier metal film.

FIGS. 13A to 13D are sectional views of the external electrode of FIG. 4 during consecutive steps of fabrication thereof.

FIG. 14 is a sectional view of an external electrode according to a second embodiment of the present invention.

FIG. 15 is a sectional view of the external electrode of FIG. 14 during a step of fabrication thereof.

FIG. 16 is a sectional view of an external electrode according to a third embodiment of the present invention.

FIG. 17 is a sectional view of the external electrode of FIG. 16 during a step of fabrication thereof.

FIG. 18 is a sectional view of an external electrode according to a first modification of the third embodiment.

FIG. 19 is a sectional view of an external electrode according to a second modification of the third embodiment.

FIG. 20 is a sectional view of an external electrode according to a third modification of the third embodiment.

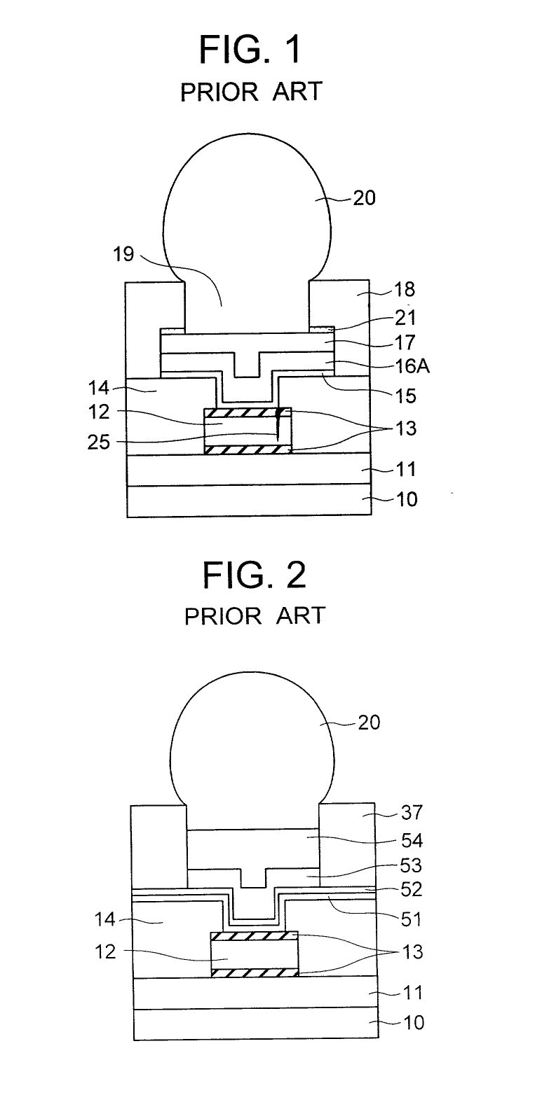

### PREFERRED EMBODIMENTS OF THE INVENTION

Now, the present invention is more specifically described with reference to accompanying drawings, wherein similar constituent elements are designated by similar reference numerals throughout the drawings.

Referring to FIG. 4, an external electrode according to a first embodiment of the present invention is formed on a dielectric film 11, which overlies a silicon substrate 10 with an intervention of a plurality of wiring layers and interlayer dielectric films (not shown). The external electrode includes a wiring pad 12 made of Al and formed on the dielectric film 11 with an intervention of an underlying TiN/Ti film 13A, which improves adhesion between the wiring pad 12 and the dielectric film 11 and thus improves reliability of the wiring structure. Another dielectric film 14 covering the wiring pad 12 has a two-layer structure including a silicon oxide (SiO₂) layer and a silicon oxynitride (SiON) layer, which have a through-hole exposing the top of the wiring pad 12.

The top of the wiring pad 12 is coated with another TiN/Ti film 13B for improving the resistance against an electro-migration failure to improve the reliability of the wiring structure. A barrier metal electrode is formed on top of the TiN/Ti film 13B in the through-hole and the vicinity thereof.

Between a solder ball 20 and the wiring pad 12, there is provided a barrier metal electrode including a solder-wetting Cu film 17, a Ni—V barrier metal film 16, an adherence Ti film 15, and the TiN/Ti film 13B. Among others, the Ni—V barrier metal film 16 has a highest barrier function for preventing the Sn component in the solder ball 20 from diffusing into the Al—Cu alloy in the wiring pad 12. In the fabrication process, these films in the external electrode are formed by sputtering over the entire area and by subsequent patterning thereof to be left in the through-hole on top of the wiring pad 12 and the vicinity of the through-hole. A polyimide coat (or passivation film) 18 is then formed on the entire area, followed by mounting the solder ball 20 on the barrier metal electrode in the through-hole. An adherence TiW film 21 is interposed between the periphery of the top of the solder-wetting Cu film 17 and the polyimide coat 18.

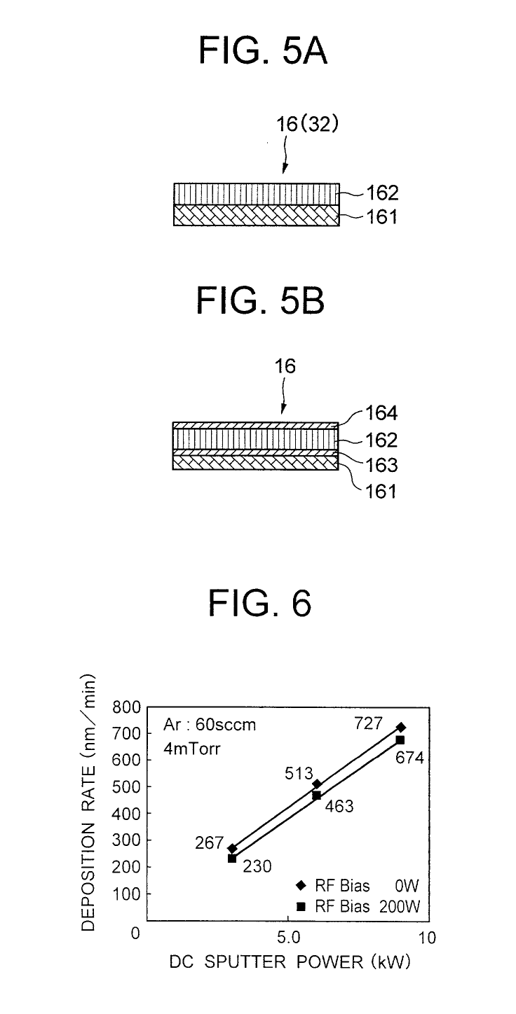

Referring to FIG. 5A, the Ni—V barrier metal film 16 made of Ni alloy has a two-layer structure including a first barrier metal layer 161 and a second barrier metal layer 162 having different crystalline structures. The lower, first barrier metal layer 161 has a granular crystalline structure made of Ni—V alloy and having a tensile internal stress. The upper, second barrier metal layer 162 has a pillar crystalline structure made of Ni—V alloy and having a compressive internal stress. Each of the first and second barrier metal layers 161 and 162 has a thickness of about 200 nm, and is formed by sputtering.

In the present embodiment, the barrier metal film 16 is made of Ni—V alloy in consideration that the Ni element generally has a higher barrier function against the Sn diffusion, and that the addition of V (vanadium) lowers the Curie temperature of the Ni element, thereby allowing Ni to be nonmagnetic, which is suited to sputtering of this alloy. In the Ni—V alloy, vanadium is added by about 7% in the present embodiment. Examples of the elements which reduce the Curie temperature of Ni by addition of small amount thereof, other than the vanadium, include tungsten (W), tantalum (Ta), silicon (Si), copper (Cu) etc. An alloy including nickel and one of these elements may be used for the barrier metal layer.

By the configuration wherein the barrier metal film 16 has both a tensile internal stress and a compressive internal stress, the overall internal stress of the barrier metal film 16 can be alleviated. This allows the underlying film such as the wiring pad 12 and the dielectric film 14 to have lower possibility of damages such as generation of crack of the wiring pad 12 or peel-off of the adjacent dielectric film 14.

The second barrier metal layer 162 having a pillar crystalline structure, if used alone in the barrier metal film 16, has a smaller path length for the grain diffusion, whereby the barrier function against the Sn diffusion is not sufficient in the barrier metal film 16 The barrier function against the Sn diffusion is mostly provided by the lower, first barrier metal layer 161, which has a sufficient path length along the crystalline boundary.

Alternatively, the barrier metal film 16 in FIG. 4 may have a four-layer structure such as shown in FIG. 5B. The four-layer structure includes a first Ni—V barrier metal layer 161 having a granular crystalline structure, a first amorphous Ni—V layer 163 having a thickness of about 10 nm, a second Ni—V barrier metal layer 162 and a second amorphous Ni—V layer 164 having a thickness of about 20 nm, which are consecutively formed on the adherence Ti film 15. Each of the amorphous Ni—V layers 163 and 164 enhances the barrier function of the underlying barrier metal Ni—V layer 161 or 162 against the Sn diffusion.

The four-layer structure as shown in FIG. 5B can be obtained by reducing the substrate temperature or setting the DC sputtering power at an extremely lower value during formation of the barrier metal film 16 by sputtering.

It is difficult to obtain a large thickness for the amorphous film because the amorphous film has an internal stress similar to the internal stress of the film having a granular crystalline structure, because the surface temperature of the substrate rises due to the collisions by plasma if the sputtering time is long, and because the plasma discharge is unstable in the case of lower power. However, it is confirmed by the experiments that the amorphous film as thin as 10 nm had a satisfactory barrier function against the Sn diffusion.

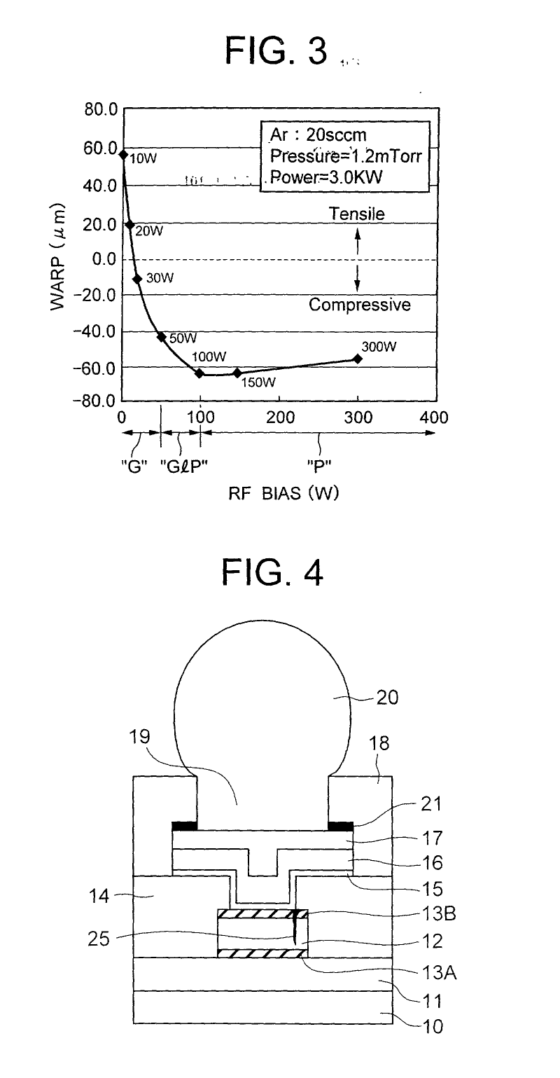

The two-layer barrier metal film 16 can be obtained by controlling the RF bias power applied during the sputtering. Referring again to FIG. 3, there is shown the relationship, obtained by experiments, between the RF bias power during the sputtering and the amount of wafer warp caused by the sputtered Ni—V barrier metal film. In the experiments, the Ni—V barrier metal film is directly formed on the wafer. The crystalline structure of the barrier metal film thus obtained is also shown along the abscissa on which the RF bias power is plotted.

The sputtering conditions were as follows: the Ar flow rate in the chamber was 20 sccm; the chamber pressure was 1.2 mTorr; DC sputtering power was 3.0 kW; film thickness was 270 nm; and the RF bias frequency was 400 kHz. The wafer warp was plotted for RF bias powers of 0, 10, 20, 50, 100, 150, 200 and 300 watts. The resultant barrier metal films were observed by an electron microscope.

As understood from FIG. 3, the wafer warp exhibits zero for a RF bias power between 20 watts and 30 watts. More specifically, the internal stress in the sputtered Ni—V film changes from a tensile stress to a compressive stress at this RF bias power. In addition, it was confirmed from the photograph by the electron microscope that a uniform bias power was not applied over the entire area of the wafer at a bias power between 50 watts and 100 watts wherein the crystalline structure shifts from the granular structure to the pillar structure. In this case, the granular crystalline structure and the pillar crystalline structure were observed in the peripheral region and the central region, respectively, with a coaxial arrangement in the resultant film.

In other words, if the RF bias power is lower than the specified value, the resultant Ni—V film has a granular crystalline structure, with the DC sputtering power maintained at 3.0 kW, whereas if the RF bias power is higher than the specified value, the resultant Ni—V film has a pillar crystalline structure. In the fabrication of the semiconductor device of the present embodiment, the RF bias power is set at zero to form a first barrier layer 161 having a thickness of 200 nm, whereas the RF bias power is set at 200 watts, for example, to form the second barrier metal layer 162 having a thickness of 200 nm.

Referring to FIG. 6, there is shown a graph showing the relationship between the deposition rate and the DC sputtering power obtained during formation of a Ni—V alloy film, with a RF bias power set at 0 and 200 watts. The process conditions were such that n the Ar flow rate in the chamber is 60 sccm and the chamber pressure is set at 4 mTorr. As understood from FIG. 6, raising the RF bias power from 0 to 200 watts reduces the deposition rate by 8 to 15%. By obtaining this relationship in advance, the deposition time length is determined for obtaining a specified film thickness.

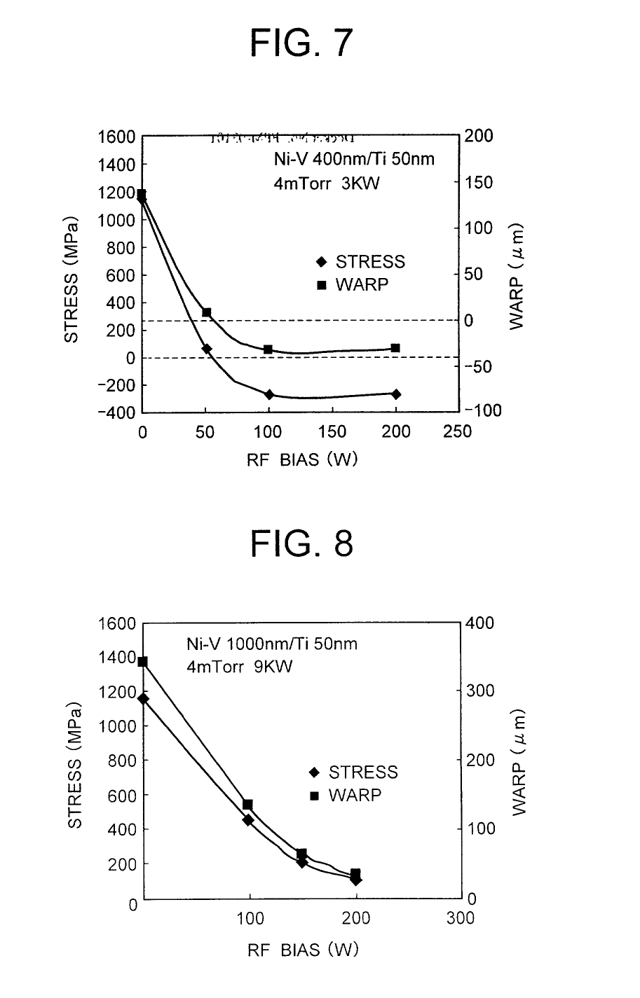

FIG. 7 shows the relationship between the internal stress of the sputtered Ni—V alloy film and the RF bias power applied to the substrate, and the relationship between the wafer warp and the RF bias power, which were obtained in the process wherein a Ni—V alloy film having a thickness of 400 nm is sputtered onto a 50-nm-thick adherence Ti film. The chamber pressure was 4 mTorr, and the DC sputtering power was set at 3 kW As understood from FIG. 7, the internal stress of the sputtered Ni—V alloy film changes from the tensile stress to the compressive stress at a RF bias power of about 40 watts. In addition, the wafer warp assumes zero at a RF bias power of about 50 watts. FIG. 7 shows the fact that a Ni—V alloy film having a desired tensile internal stress or compressive internal stress can be formed by controlling the RF bias power while employing a suitable DC sputtering power.

In other experiments, a Ni—V alloy film having a thickness of 400 nm was sputtered onto a wafer having a diameter of 200 mm while applying a variety of RF bias powers onto the wafer, with the DC sputtering power and the chamber pressure set at 6 kW and 4 mTorr, respectively. The structure of the Ni—V alloy film was observed by an electron microscope at several positions residing between the periphery and the center of each wafer. The Ni—V alloy film had a granular crystalline structure over the entire area of the wafer obtained by a zero RF bias power. The Ni—V alloy film had a substantially pillar crystalline structure at positions between the periphery and 75 mm apart from the periphery, and a granular crystalline structure at positions in the central area of the wafer obtained by a RF bias power of 50 watts. The Ni—V alloy film had a pillar crystalline structure over the entire area of the wafer obtained by a RF bias power of 200 watts.

For another wafer, the RF bias power is set at zero for an initial stage for forming a 200-nm-thick Ni—V alloy layer, and then raised up to 200 watts for forming another 200-nm-thick Ni—V alloy layer. In this wafer, the resultant Ni—V alloy film had a two-layer structure, wherein the lower 200-nm-thick Ni—V alloy layer had a granular crystalline structure whereas the upper 200-nm-thick Ni—V alloy layer had an excellent pillar crystalline structure.

FIG. 8 shows the relationship between the film stress and the RF bias power and the relationship between the wafer warp and the RF bias power, which were obtained for the case wherein a Ni—V alloy film as thick as 1000 nm was formed. The process conditions were such that the chamber pressure was 4 mTorr and the DC sputtering power was 9 kW. As understood from FIG. 8, for the case wherein the Ni—V alloy film has a larger thickness, the internal stress of the Ni—V alloy film shifts upward, or toward the tensile stress side, whereby the Ni—V alloy film has a tensile stress therein even with a RF power of 200 watts.

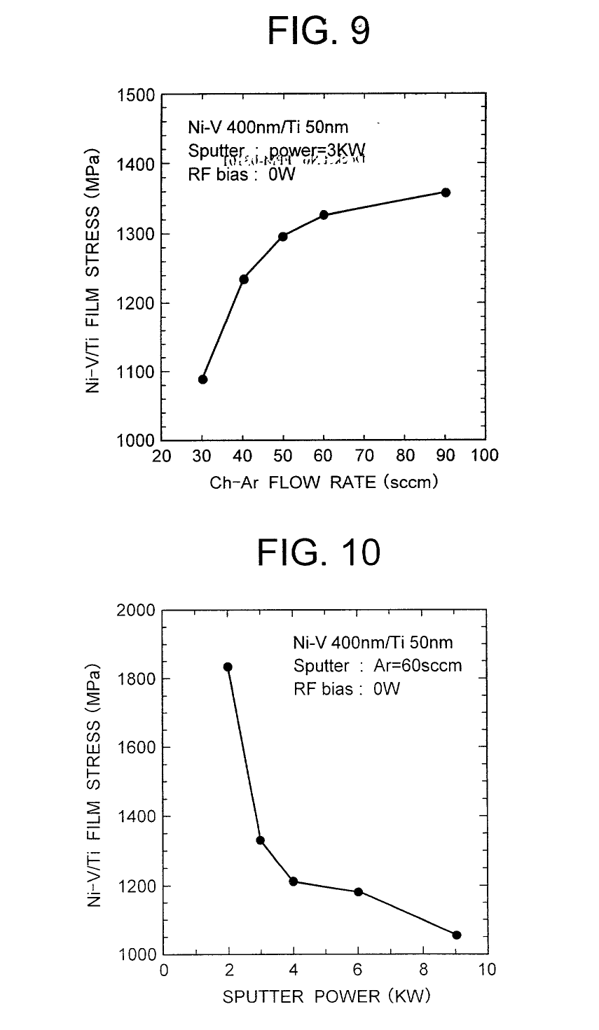

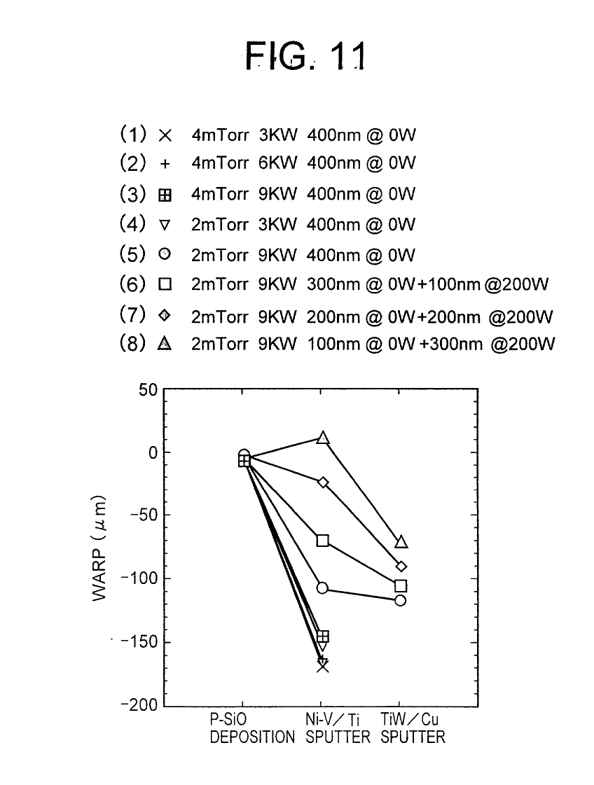

FIGS. 9 and 10 show the relationship between the film stress and the Ar flow rate in the chamber, and the relationship between the film stress and the DC sputtering power, respectively. As understood from these drawings, there is a tendency that a lower flow rate for the Ar gas, i.e., a lower sputtering pressure, as well as a higher sputtering power provides a lower stress for the Ni—V alloy film. This means that suitable sputtering conditions, such as pressure, power, film thickness and film structure, should be selected for forming a barrier metal film which does not adversely affect the underlying wiring pad or the adjacent structure. In particular, a suitable film thickness should be selected for a desirable Ni—V alloy film.

FIG. 11 shows the wafer warp measured at fabrication stages for samples of the external electrode, with the process conditions being varied. The process conditions employed are shown in FIG. 11, wherein the chamber pressure, DC sputtering power, film thickness and bias power are recited in this order for the samples (1) to (5) of the single-layer barrier metal film. For the two-layer barrier metal film tabulated as the last three samples (6) to (8), the film thickness of the upper Ni—V layer and the bias power are additionally recited for each sample.

For example, sample (1) is directed to a single-layer structure and shows 4 mTorr for the chamber pressure, 3 kW for the DC sputtering power, 400 nm for the film thickness and zero watt for the RF bias power, whereas sample (6) is directed to a two-layer structure and shows 2 mTorr for the chamber pressure, 9 kW for the DC sputtering power, 300 nm for the film thickness of the first layer, zero watt for the RF bias power for the first layer, 100 nm for the thickness of the second layer, and 200 watts for the bias power for the second layer.

For fabricating these samples: step (a), a silicon oxide film is deposited using a plasma-enhanced CVD technique on a wafer; step (b), followed by forming an adherence Ti film and a Ni—V alloy film having a single- or two-layer structure; and step (c), followed by forming a solder-wetting Cu film and an adherence TiW film thereon. At each of steps (a), (b) and (c), the wafer warp was measured, as shown in FIG. 11. Table 1 shows the measured values for each sample.

TABLE 1

| Sample | Final Stress | Wafer warp at (b) | Wafer warp at (c) |
|---|---|---|---|
| 1 | 1230 | −164.84 | — |
| 2 | 1180 | −158.74 | — |
| 3 | 1050 | −139.46 | — |
| 4 | 1090 | −146.68 | — |
| 5 | 770 | −105.81 | −114.01 |
| 6 | 461 | −65.6 | −106.01 |
| 7 | 169 | −22.7 | −90.2 |
| 8 | −157 | 17.27 | −66.54 |

In Table 1, the recited stress (Mpa) is positive for the tensile strain and negative for the compressive strain, whereas the recited wafer warp is negative for the tensile side and positive for the compressive side.

As understood from FIG. 11, after the adherence Ti film and the Ni—V alloy film having a single-layer structure were formed by sputtering, the wafer warp was shifted toward the tensile side due to the Ni—V alloy film having a tensile internal stress. On the other hand, after the adherence Ti film and the Ni—V alloy film having a two-layer structure were formed by sputtering, the large tensile stress was alleviated. After the solder-wetting Cu film and the adherence TiW film were subsequently formed, the wafer warp was shifted also toward the tensile side. Thus, it should be noted before sputtering the Ni—V alloy film that the wafer warp may be shifted toward the tensile side by forming the solder-wetting Cu film and the adherence TiW film subsequent to sputtering of the Ni—V alloy film.

As will be understood from FIGS. 9 and 10, a lower chamber pressure, i.e., a higher degree of vacuum shifts the internal stress of the Ni—V alloy film toward the compressive side. This means that the adverse affect to the wafer by the wafer warp can be controlled to a minimum by controlling the internal stress of the Ni—V alloy film while controlling the chamber pressure in consideration of the internal stresses applied by the other conductive films and the current wafer warp.

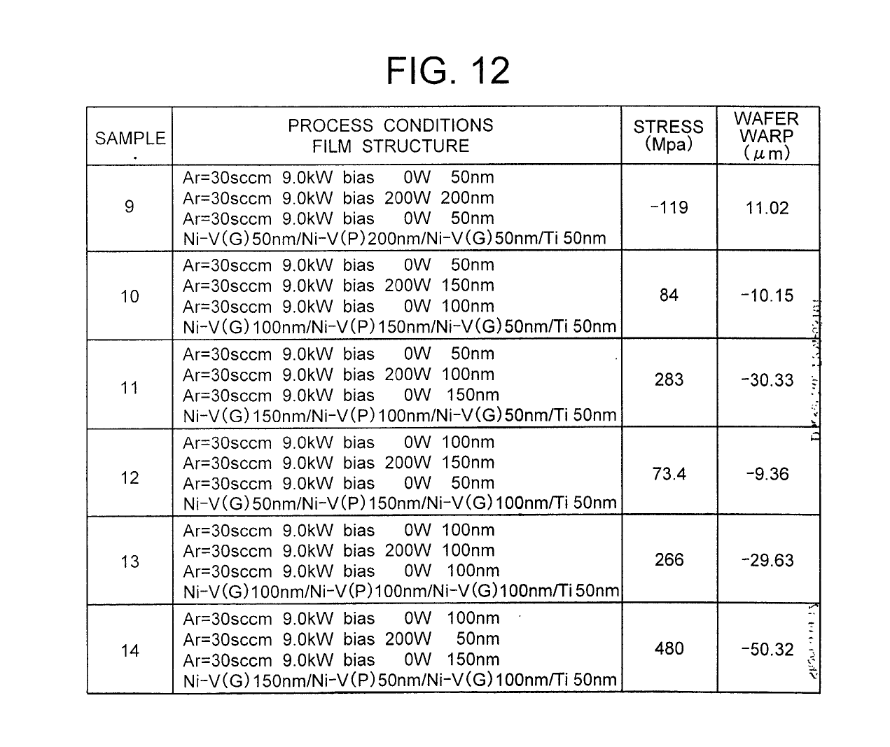

In the above embodiment, the Ni—V alloy film having a single-layer or two-layer structure is discussed. However, a Ni—V alloy film of the embodiment may have a three- or more-layer structure including at least one layer having a tensile stress and at least one layer having a compressive stress. FIG. 12 shows a table obtained by other samples of the Ni—V alloy film having a total thickness of 300 nm and formed by a variety of process conditions.

In the second column of each sample of the table of FIG. 12, the three rows represent the process conditions for respective Ni—V alloy layers consecutively formed on a Ti film. The fourth row represents the film structure, wherein a granular crystalline structure is represented by (G) whereas a pillar crystalline structure is represented by (P). For example, the film structure in sample (9) is such that the underlying layer is a Ti film having a thickness of 50 nm, the first Ni—V alloy layer has a granular crystalline structure having a thickness of 50 nm, the second Ni—V alloy layer has a pillar crystalline structure having a thickness of 200 nm, and the third Ni—V alloy layer has a granular crystalline structure having a thickness of 50 nm. In sample (9), the process conditions for the first to third Ni—V alloy layers are recited in the first to third row in each sample, wherein Ar flow rate, DC sputtering power, RF bias power and the film thickness are recited in this order for each layer. Descriptions in other samples (10) to (14) are similar to those in sample (9).

As understood from FIG. 12, a Ni—V alloy film having a three-layer structure also improves the internal stress and can alleviate the wafer warp, similarly to the two-layer structure.

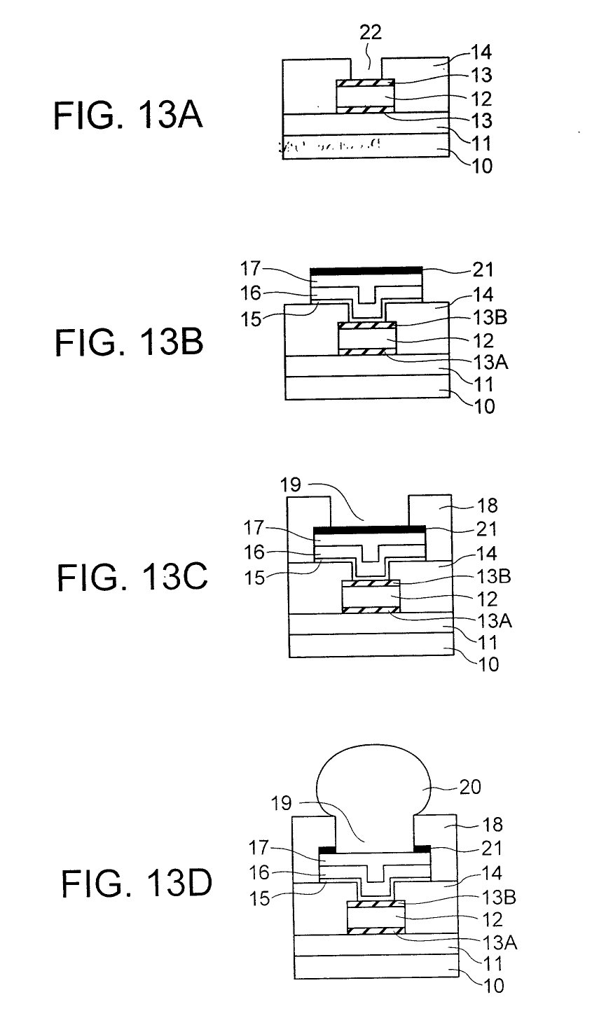

Referring to FIGS. 13A to 13D, there are shown consecutive steps for fabricating the external electrode of the first embodiment. First, a multi-layer interconnection structure including a plurality of interconnect layers and a plurality of interlayer dielectric films is formed on a silicon substrate 10, followed by formation of TiN/Ti film 13A, a wiring pad 12 as a part of the Al interconnects, and a TiN/Ti film 13B on a dielectric film 11 Subsequently, an interlayer dielectric film 14 having a two-layer structure including SiO₂ and SiON layers, followed by patterning thereof to form a through-hole for exposing the top of the wiring pad 12, as shown in FIG. 13A.

Thereafter, a Ti (or TiW) adherence film 15, a barrier metal film 16 made of Ni—V alloy having a two-layer structure, solder-wetting Cu film 17 and an adherence TiW film 21 are consecutively deposited by sputtering on top of the interlayer dielectric film 14 and within the through-hole 22, thereby forming a barrier metal film structure. The barrier metal film structure is then patterned to form a barrier metal electrode having dimensions suited to mount thereon a solder ball, as shown in FIG. 13B, followed by forming a polyimide coat 18 thereon. The polyimide coat 18 is then patterned to form an opening for exposing top of the barrier metal electrode, as shown in FIG. 13C.

The exposed surface of the topmost TiW film of the barrier metal electrode is then removed by wet etching. A solder ball is then mounted on the barrier metal electrode to protrude from the top of the through-hole 19, thereby obtaining the external electrode structure as shown in FIG. 13D. The Ni—V alloy film 16 acting as a barrier metal film having a two-layer structure has a high barrier function against the diffusion of the Sn component in the solder ball 20. The Ni—V alloy film 20 also reduces the internal stress in the barrier metal electrode as a whole, thereby preventing generation of a crack in the wiring pad 12 or peel-off of the dielectric film 14, which may occur due to the internal stress.

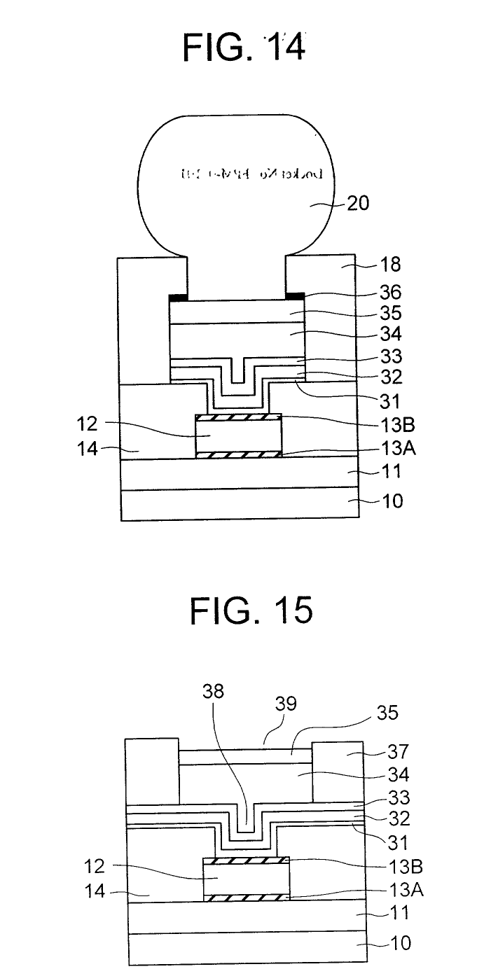

Referring to FIG. 14, an external electrode according to a second embodiment of the present invention is similar to the external electrode shown in FIG. 4 except for the structure of the barrier metal electrode. More specifically, the barrier metal electrode shown in FIG. 14 includes an adherence Ti film 31 as a first conductive film, a sputtered Ni—V barrier metal film 32 as a second conductive film, a seed Cu film 33 as a third conductive film, a plating Ni barrier film 34 as a fourth conductive film, a solder-wetting Cu film 35 as a fifth conductive film, and an adherence Ti film 36 disposed between the solder-wetting Cu film 35 and the polyimide coat 18. The Ni—V barrier metal film 32 has a two-layer structure, such as shown in FIG. 5A, including a first barrier metal layer having a granular crystalline structure and a second barrier metal layer having a pillar crystalline structure.

In the structure of the second embodiment, the seed Cu film 33 overlying the sputtered Ni—V barrier metal film 32 improves the adherence between the Ni—V barrier metal film 32 and the overlying film, and also improves the compactness of the overlying plating Ni barrier film 34. The seed Cu film 33 has a superior adherence to the overlying plating Ni barrier film 34. The Ni—V barrier film 32 is sputtered in a vacuum ambient, and the seed Cu film 33 is subsequently sputtered in the same vacuum ambient, whereby occurrence of a passive Ni oxide film on the Ni—V barrier metal film 32 can be prevented. An oxide film which may be formed on the seed Cu film 33 can be removed with ease, whereby the plating Ni barrier film 34 formed thereon has an improved compactness and an improved adherence function. It is to be noted that the plating Ni barrier film 34 has a granular crystalline structure having a higher barrier function. In an alternative of the second embodiment, a seed Au film may be used instead of the seed Cu film 33.

For manufacturing the external electrode of FIG. 14, the structure shown in FIG. 13A is first formed similarly to the first embodiment.

Subsequent to the step of FIG. 13A, an adherence Ti (or TiW) film 31, Ni—V barrier metal film 32 and a seed Cu film 33 are sputtered onto the dielectric film 11 having a two-layer structure and within the through-hole 22 therein. A photoresist film 37 is then formed thereon, followed by patterning the photoresist film 37 to form an opening 38 for exposing the top of the seed Cu film 33. The plating Ni barrier film 34 is then formed within the opening 38 by using a selective plating technique, followed by forming the solder-wetting Cu film 35 also by using the selective plating technique. The structure obtained by the above steps is shown in FIG. 15. The Ni—V barrier metal film 32 has a two-layer structure such as shown in FIG. 5A.

After removing the photoresist film 37, an adherence TiW film 36 is sputtered onto the plating Cu film 35. The adherence TiW film 36, seed Cu film 33, Ni—V barrier metal film 32, and adherence Ti film 31 are consecutively etched by using a photoresist mask, followed by forming a polyimide coat 18 thereon. The polyimide coat 18 is subjected to patterning to form an opening 39 for exposing the barrier metal electrode. The topmost adherence TiW film 36 of the barrier metal electrode and the top portion of the solder-wetting Cu film 35 are removed by wet etching, followed by mounting the solder ball 20 within the opening 39, thereby obtaining the structure of FIG. 14.

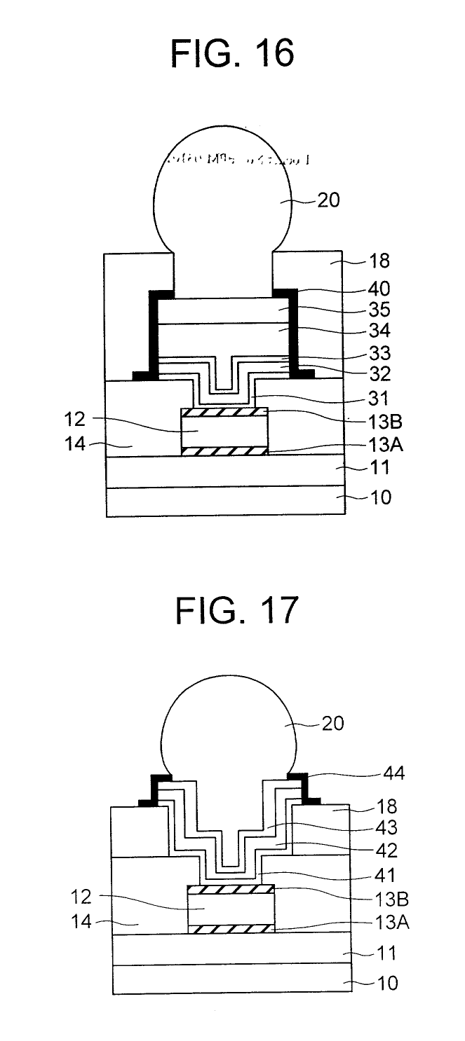

Referring to FIG. 16, an external electrode in a semiconductor device according to a third embodiment of the present invention is similar to the external electrode in the second embodiment except for the structure of the adherence TiW film. More specifically, the adherence TiW film 40 is formed by sputtering, after the first through fifth conductive layers 31 to 35 are patterned. The adherence TiW film 40 covers the edge portions of the first through fifth conductive layers 31 to 35, the dielectric film 14 having a two-layer structure in the vicinity of the edge portions of thereof, the peripheral area of the top of the solder-wetting Cu film 35. The portion of the TiW film 40 corresponding to the location of the solder ball 20 is removed together with the corresponding portion of the solder-wetting Cu film 35 by wet etching, similarly to the second embodiment.

In the third embodiment, the adherence TiW film 40 acts as a protective layer which prevents the Sn component in the solder ball 20 mounted on the barrier metal electrode from diffusing toward the barrier metal electrode through the internal of the polyimide coat 18 and the interface between the conductive layers. The TiW film 40 has a lower reactivity with the solder, and thus is suited to this purpose.

Referring to FIG. 17, an external electrode in a semiconductor device according to a fourth embodiment of the present invention includes a barrier metal electrode which is formed after the polyimide coat 18 is formed. More specifically, the polyimide coat 18 is formed on the dielectric film 14 having a two-layer structure such as shown in FIG. 5A and a through-hole on the wiring pad 12, and patterned to have an opening for exposing the top of the wiring pad 12. Subsequently, a barrier metal electrode film structure including an adherence Ti film 41, Ni—V barrier metal film 42 having a two-layer structure, and a solder-wetting Cu film 43 are consecutively formed by sputtering. After the barrier metal film structure is patterned, the adherence TiW film 44 is deposited by sputtering and then patterned. The patterned TiW film covers the edges of the barrier metal electrode and prevents the Sn component in the solder ball 20 from diffusing toward the barrier metal electrode through the interface between the conductive layers, similarly to the external electrode of FIG. 16.

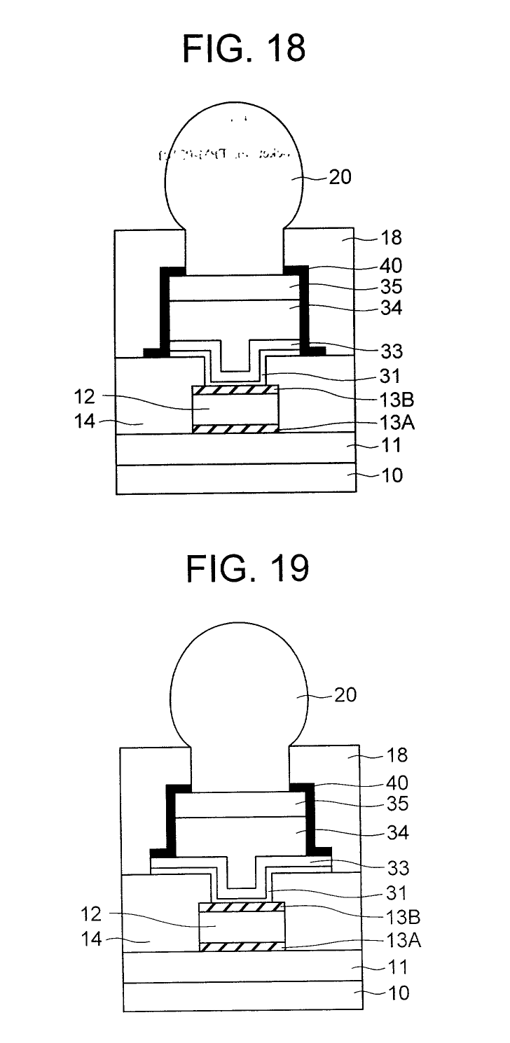

Referring to FIG. 18, an external electrode according to a modification of the third embodiment of the present invention is manufactured as follows. First, a multi-layer interconnection structure including a plurality of interconnect layers and a plurality of interlayer dielectric films is formed on a silicon substrate 10, followed by formation of TiN/Ti film 13A, a wiring pad 12 as a part of the Al interconnects, and a TiN/Ti film 13B on a dielectric film 11. Subsequently, an interlayer dielectric film 14 having a two-layer structure including SiO₂ and SiON layers, followed by patterning thereof to form a through-hole for exposing the top of the wiring pad 12, as shown in FIG. 13A.

Thereafter, a Ti (or TiW) adherence film 31 and seed Cu film 33 are consecutively deposited by sputtering on top of the interlayer dielectric film 14. The plating Ni barrier film 34 and the solder-wetting Cu film 35 are then formed by using a selective plating technique. The adherence film 31 and the seed Cu film 33 are then patterned, then a adherence TiW film 40 is sputtered and patterned. The polyimide coat 18 is then coated and patterned to form an opening. The exposed surface of the topmost TiW film of the barrier metal electrode is then removed by wet etching. A solder ball is then mounted on the barrier metal.

Referring to FIG. 19, an external electrode according to a second modification of the third embodiment of the present invention is similar to the external electrode shown in FIG. 18 except for the patterning process of the barrier metal electrode. The plating Ni barrier film 34 and the solder-wetting Cu film 35 are formed by using a selective plating technique, and the adherence TiW film 40 is formed by sputtering. Then, the adherence TiW film 40, the seed Cu film 33 and the adherence Ti(or TiW) film 31 are patterned. The polyimide coat 18 is then coated and patterned to form an opening. The exposed surface of the topmost TiW film of the barrier metal electrode is then removed by wet etching. A solder ball is then mounted on the barrier metal.

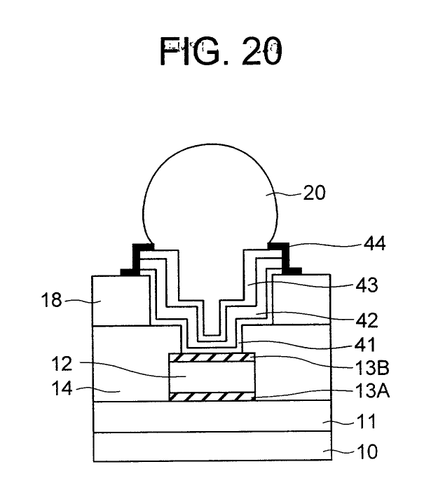

Referring to FIG. 20, an external electrode according to a third modification of the third embodiment of the present invention is similar to the external electrode shown in FIG. 19 except for the patterning process of the polyimide film. After the polyimide coat 18 is coated and patterned to form an opening, the barrier metal electrode which includes the Ti (or TiW) adherence film 31, the seed Cu film 33, the plating Ni barrier film 34 and the solder-wetting Cu film 35, is formed. A solder ball is then mounted on the barrier metal.

Since the above embodiments are described only for examples, the present invention is not limited to the above embodiments and various modifications or alterations can be easily made therefrom by those skilled in the art without departing from the scope of the present invention.

What is claimed is:

1. A semiconductor device comprising an external electrode having a wiring pad, a barrier metal electrode and a solder ball consecutively formed on a wafer, said barrier metal electrode including a plurality of barrier metal layers having common elements and having different internal stresses and/or different crystalline structures.

2. The semiconductor device as defined in claim 17 wherein said barrier metal layers include nickel or nickel alloy.

3. The semiconductor device as defined in claim 2, wherein said nickel alloy is selected from the group consisting of nickel vanadium, nickel tungsten, nickel tantalum, nickel silicon and nickel copper alloys.

4. The semiconductor device as defined in claim 1, wherein said barrier metal layers include a first barrier metal layer having a tensile internal stress and a second barrier metal layer having a compressive internal stress.

5. The semiconductor device as defined in claim 1, wherein said barrier metal layers include a first barrier metal layer having a granular crystalline structure and a second barrier metal layer having a pillar crystalline structure.

6. The semiconductor device as defined in claim 5, wherein said barrier metal layers further include first and second amorphous layers made of nickel or nickel alloy and formed on said first and second barrier metal layers, respectively.

7. The semiconductor device as defined in claim 1, wherein said barrier metal electrode includes a protective layer covering edges of said barrier metal layers.

8. A semiconductor device comprising an external electrode having a wiring pad, a barrier metal electrode and a solder ball consecutively formed on a wafer, said barrier metal electrode including first through fifth conductive films consecutively formed on said wiring pad, wherein said second and fourth conductive films are barrier metal films, and said fourth conductive film is a plating film.

9. The semiconductor device as defined in claim 8, wherein said second conductive film includes a first conductive layer having a granular crystalline structure and a second conductive layer having a pillar crystalline structure.

10. The semiconductor device as defined in claim 9, wherein said second conductive film includes a first conductive layer having a tensile internal stress and a second conductive layer having a compressive internal stress.

11. The semiconductor device as defined in claim 8, wherein said third conductive film includes copper, and said second and fourth conductive films include nickel as a main component thereof.

12. The semiconductor device as defined in claim 8, wherein said fourth conductive film has a thickness larger than a thickness of said second conductive film.

13. The semiconductor device as defined in claim 8, wherein said barrier metal electrode further includes a protective film for covering edge portions of said first through fifth conductive films.

14. A method for manufacturing an external electrode in a semiconductor device, said method comprising the steps of:
forming a wiring pad on a wafer;
forming a plurality of barrier metal layers on said wiring pad; and
forming a solder ball on said barrier metal layers.

15. The method as defined in claim 14, wherein said plurality of barrier metal layers include nickel or nickel alloy and have different internal stresses.

16. The method as defined in claim 14, wherein said plurality of barrier metal layers include nickel or nickel alloy and have different crystalline structures.

17. The method as defined in claim 14, wherein said plurality of barrier metal layers include an amorphous layer made of nickel or nickel alloy.

18. The method as defined in claim 14, wherein said nickel alloy is selected from the group consisting of nickel vanadium, nickel tungsten, nickel tantalum, nickel silicon and nickel copper alloys.

19. The method as defined in claim 14, wherein said barrier metal layers forming step includes the step of controlling a bias voltage applied to said wafer to control an internal stress or crystalline structure of said barrier metal layers.

20. A method for manufacturing an external electrode in a semiconductor device, said method comprising the steps of:
forming a wiring pad on a wafer;
forming a first barrier metal film made of nickel or nickel alloy on said wiring pad by sputtering in a vacuum ambient;
forming a seed film on said first barrier metal film in said vacuum ambient;
forming a second barrier metal film made of nickel by plating on said seed film; and
forming a solder ball on said second barrier metal film.

21. The method as defined in claim 20, wherein said nickel alloy is selected from the group consisting of nickel vanadium, nickel tungsten, nickel tantalum, nickel silicon and nickel copper alloys.

22. The method as defined in claim 20, wherein said first barrier metal film forming step includes the step of controlling a bias voltage applied to said wafer to control an internal stress or crystalline structure of said first barrier metal film.

23. A semiconductor device comprising an external electrode having a wiring pad, a barrier metal electrode and a solder ball consecutively formed on a wafer, said barrier metal electrode including first through fourth conductive films consecutively formed on said wiring pad, wherein said third conductive films are barrier metal films, and said third conductive film is a plating film.

24. The semiconductor device as defined in claim 23, wherein said second and fourth conductive film includes copper and said a third conductive layer includes nickel as a main component thereof.

25. The semiconductor device as defined in claim 23, wherein said fourth conductive film has a thickness larger than a thickness of said second conductive film.

26. The semiconductor device as defined in claim 23, wherein said barrier metal electrode includes a protective layer covering edges of said barrier metal layers.

27. The semiconductor device as defined in claim 26, wherein said protective layer includes conductive layer or bilayer of conductive layer and dielectric layer.
